(19) United States
(12) Patent Application Publication
(10) Pub. No.: US 2015/0054070 A1
(43) Pub. Date: Feb. 26, 2015

(54) Electrostatic Discharge Protection Device and Manufacturing Method Thereof

(71) Applicants: Tsung-Yi Huang, HsinChu (TW); Wen-Yi Liao, HsinChu (TW)

(72) Inventors: Tsung-Yi Huang, HsinChu (TW); Wen-Yi Liao, HsinChu (TW)

(73) Assignee: RICHTEK TECHNOLOGY CORPORATION, Chupei City (TW)

(21) Appl. No.: 13/975,024

(22) Filed: Aug. 23, 2013

(51) Int. Cl. H01L 29/78; H01L 29/66

(52) U.S. Cl. CPC H01L 29/7826; H01L 29/66681
USPC 257/336; 438/286

(57) ABSTRACT

The present invention discloses an electrostatic discharge (ESD) protection device and a manufacturing method thereof. The ESD protection device includes: a P-type well, a gate structure, an N-type source, an N-type drain, and a P-type lightly doped drain. The P-type lightly doped drain is formed in the P-type well, and at least part of the P-type lightly doped drain is beneath a spacer of the gate structure to reduce a trigger voltage of the electrostatic discharge protection device.

### BACKGROUND OF THE INVENTION

1. Field of Invention

The present invention relates to an electrostatic discharge (ESD) protection device and a manufacturing method thereof; particularly, it relates to such ESD protection device and manufacturing method thereof wherein an ESD trigger voltage is reduced.

2. Description of Related Art

FIG. 1A shows a schematic diagram of a typical electrostatic discharge (ESD) protection device 100 and a protected circuit/device 1. As shown in FIG. 1A, the ESD protection device 100 and the protected circuit/device 1 are connected between a pad 2 and a ground level (GND) or power supply level (Vdd) in parallel. When one of the terminals which are coupled to the ESD protection device 100 and the protected circuit/device 1 contacts static charges (indicated by a lightening symbol shown in FIG. 1A), the ESD protection device 100 is triggered, such that the high voltage and the high current caused by the static charges are released by the ESD protection device 100, to prevent the protected circuit/device 1 from being damaged by the static charges.

The ESD protection device 100 is for example an N-type metal oxide semiconductor (MOS) device as shown in FIG. 1B. The ESD protection device 100 includes a P-type substrate 11, an isolation structure 13, an N-type lightly doped drain 14, a gate 15, a source 16, and a drain 17. In one application, the substrate 11, the gate 15, and the source 16 are electrically connected to a ground level (GND), and the drain 17 is electrically connected to the pad 2. When the pad 2 contact static charges, a current I charges a capacitor which is formed by the lightly doped drain 14 and the P-type substrate 11, such that an electric field with a high voltage V is formed between the N-type lightly doped drain 14 and the P-type substrate 11. When the high voltage V exceeds a breakdown voltage of the ESD protection device 100, an electrical breakdown occurs in the ESD protection device 100. When the electrical breakdown occurs, the base voltage of a parasitic bipolar junction transistor (BJT, indicated by dash lines shown in the figure) of the ESD protection device 100 increases, and the parasitic BJT turns ON in a self-bias mode. When the high voltage V (i.e., the drain voltage) exceeds a trigger voltage, the current I (i.e., the current flowing from the drain 17 and the substrate 11) increases dramatically as shown in FIG. 1C.

FIG. 1C shows the voltage-current (V-I) characteristic curve of the ESD protection device 100. As shown in the figure, when the high voltage V caused by the static charges exceeds the trigger voltage, the ESD protection device 100 releases the high voltage V and the current I caused by the static charges. Note that, as shown in FIG. 1C, the ESD protection device 100 should be designed according to the ESD design window which is related to the breakdown voltage (BV) of the protected circuit/device 1 and the power supply voltage level (Vdd). More specifically, the trigger voltage of the ESD protection device 100 should be lower than the breakdown voltage of the protected circuit/device 1, i.e., the ESD protection device 100 needs to be triggered to release the static charges before breakdown occurs in the protected circuit/device 1. Besides, the breakdown voltage of the ESD protection device 100, which is lower than the trigger voltage, should be higher than the power supply voltage Vdd so that the ESD protection device 100 does not break down when the protected circuit/device 1 is in normal operation.

FIG. 1D shows an enlarged diagram of the part of FIG. 1B which is indicated by a dashed circle. As shown in the figure, when the static charges contact the drain 17, a high electric field is formed between the N-type lightly doped drain 14 and the P-type substrate 11. The position where the breakdown first occurs is between the N-type lightly doped drain 14 and the P-type substrate, close to the surface of the P-type substrate 11, as indicated by a star symbol shown in the figure. The drawback of such prior art is that, because the ESD protection device 100 is manufactured on the substrate 11 together with other devices, the manufacturing process steps of the ESD protection device 100 are limited by the process steps for manufacturing these other devices, and when it is desired to reduce the trigger voltage of the ESD protection device according to design or application requirements, additional manufacturing process steps are required. Besides, the trigger voltage of the prior art ESD protection device can be adjusted only in a very limited range.

Therefore, to overcome the drawbacks in the prior art, the present invention proposes an ESD protection device and a manufacturing method thereof, wherein an ESD trigger voltage can be reduced, and protection and application range of the protected circuit/device can be enhanced without increasing manufacturing process steps.

### SUMMARY OF THE INVENTION

From one perspective, the present invention provides an electrostatic discharge (ESD) protection device, which is formed in a semiconductor substrate, wherein the semiconductor substrate has an upper surface, the ESD protection device including: a P-type well, which is formed beneath the upper surface; a gate structure, which is formed on the upper surface, and part of the P-type well is located beneath the gate structure; an N-type source, which is formed in the P-type well beneath the upper surface, and the N-type source is located at one side of the gate structure; an N-type drain, which is formed beneath in the P-type well the upper surface, and the N-type drain is located at another side of the gate structure; wherein the gate structure separates the N-type source and the N-type drain, and the gate structure includes: a dielectric layer, which is formed on the upper surface; a conductive stack layer, which is formed on the dielectric layer, as a gate electrode; and a spacer layer, which is formed on sidewalls of the conductive stack layer; and a first P-type lightly doped drain, which is formed in the P-type well beneath the upper surface, and at least part of the first P-type lightly doped drain is located beneath the spacer layer.

From another perspective, the present invention provides a manufacturing method of an electrostatic discharge (ESD) protection device including: providing a semiconductor substrate with an upper surface; forming a P-type well beneath the upper surface; forming a gate structure on the upper surface, and part of the P-type well is located beneath the gate structure; forming an N-type source in the P-type well beneath the upper surface, and the N-type source is located at one side of the gate structure; forming an N-type drain in the P-type well beneath the upper surface, and the N-type drain is located at another side of the gate structure; wherein the gate structure separates the N-type source and the N-type drain, and the gate structure includes: a dielectric layer, which is formed on the upper surface; a conductive stack layer, which is formed on the dielectric layer, as a gate electrode; and a spacer layer, which is formed on sidewalls of the conductive stack layer; and forming a first P-type lightly doped drain in the P-type well beneath the upper surface, and at least part of the first P-type lightly doped drain is located beneath the spacer layer.

In one preferable embodiment, the first P-type lightly doped drain and a second P-type lightly doped drain of a low voltage device are formed by a same process step in the semiconductor substrate.

In the aforementioned embodiment, the gate structure is electrically connected to a ground level in a normal operation.

In another preferable embodiment, the first P-type lightly doped drain is formed by a P-type lightly doped drain ion implantation process step and an N-type lightly doped drain ion implantation process step, wherein the P-type lightly doped drain ion implantation process step is a same process step as a process step which forms a second P-type lightly doped drain in a low voltage device in the semiconductor substrate.

In another preferable embodiment, a P-type impurity concentration of the first P-type lightly doped drain is higher than a P-type impurity concentration of the P-type well.

The objectives, technical details, features, and effects of the present invention will be better understood with regard to the detailed description of the embodiments below.

### BRIEF DESCRIPTION OF THE DRAWINGS

FIG. 1A shows a schematic circuitry diagram of a prior art electrostatic discharge (ESD) protection device 100 and a protected circuit/device 1.

FIG. 1B shows a schematic diagram of the prior art ESD protection device 100 from cross-section view.

FIG. 1C shows the high voltage-current (V-I) characteristic curve of the ESD protection device 100.

FIG. 1D shows an enlarged diagram of the part of FIG. 1B which is indicated by a dashed circle.

FIGS. 2A-2F show a first embodiment of the present invention.

FIGS. 3A-3B show an impurity concentration profile and a voltage-current characteristic curve of the prior art ESD protection device.

FIGS. 4A-4B show a second embodiment of the present invention.

FIGS. 5A-5B show a third embodiment of the present invention.

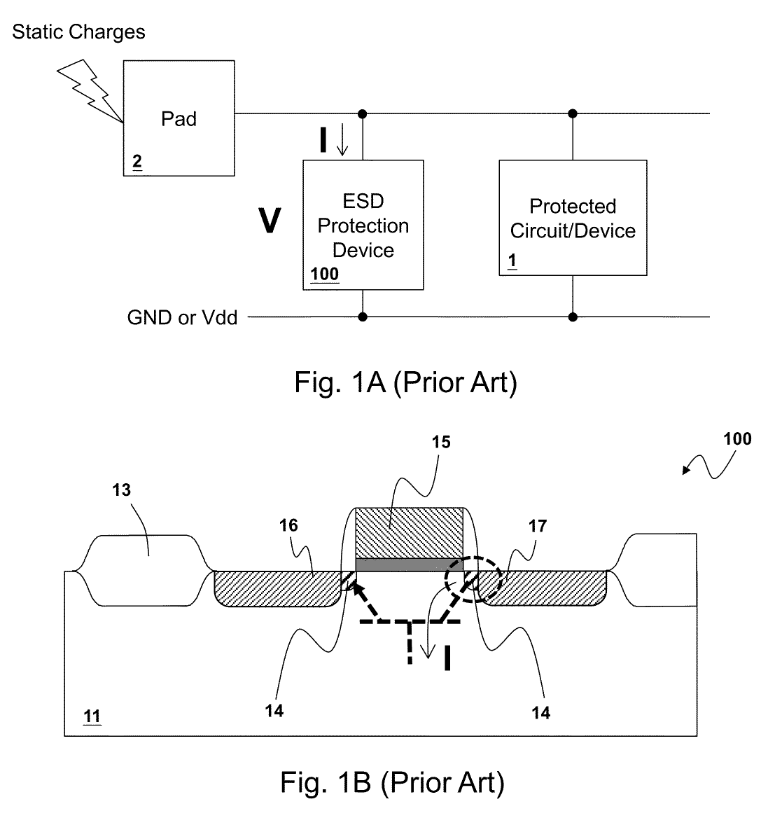

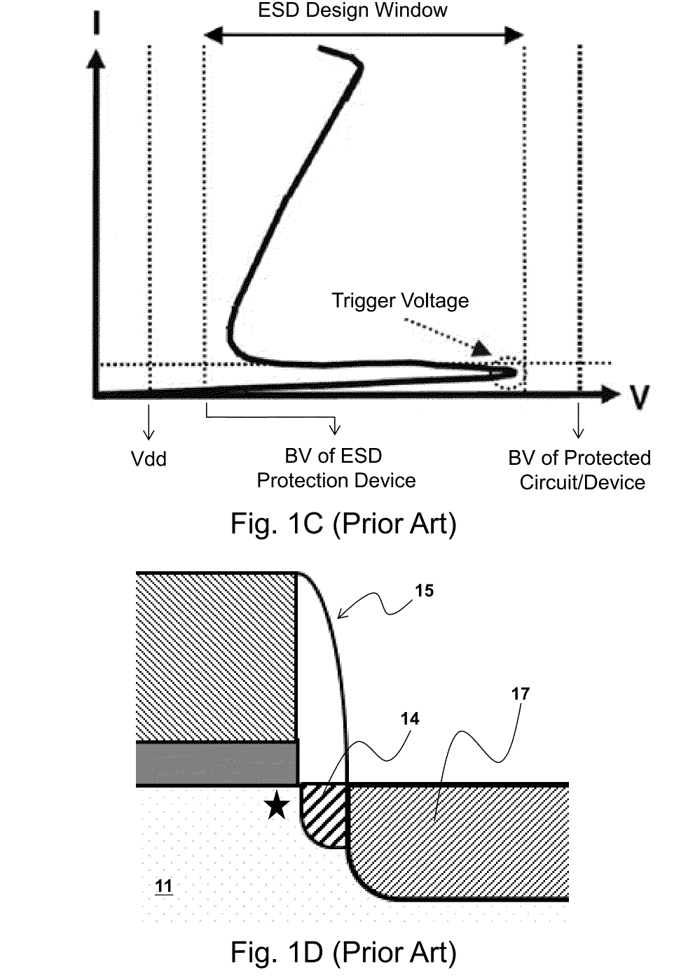

### DESCRIPTION OF THE PREFERRED EMBODIMENTS

The drawings as referred to throughout the description of the present invention are for illustration only, to show the interrelations between the regions and the process steps, but not drawn according to actual scale.

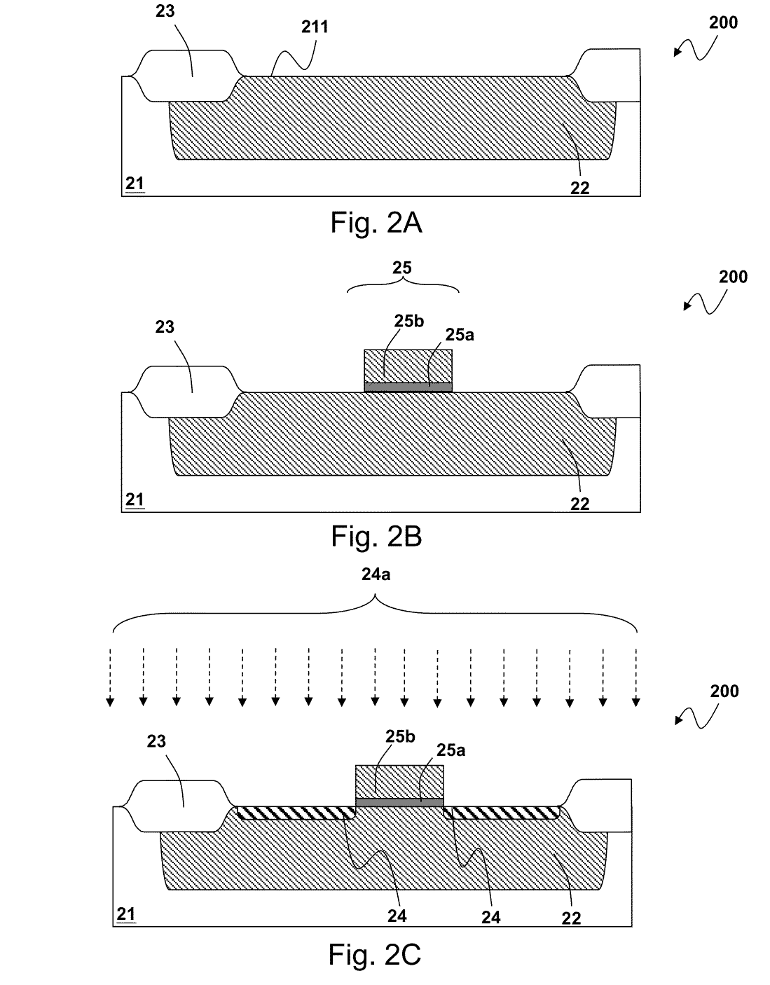

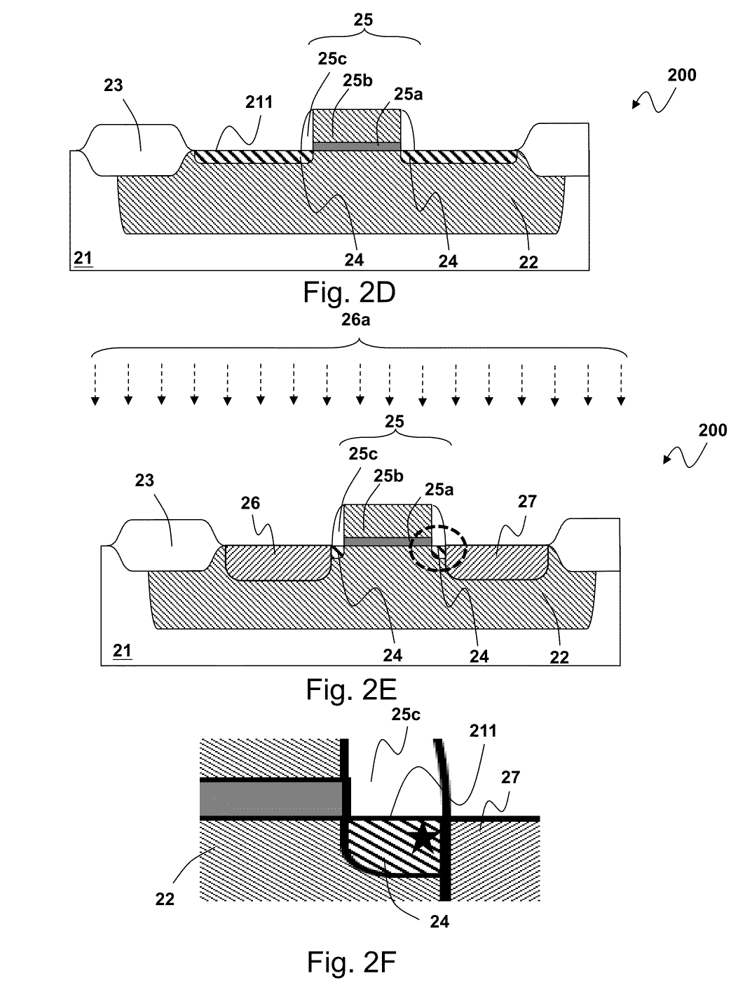

Please refer to FIGS. 2A-2F for a first embodiment according to the present invention, wherein FIGS. 2A-2F are cross-section diagrams showing a manufacturing method of an electrostatic discharge (ESD) protection device 200. As shown in FIG. 2A, first, a semiconductor substrate 21 is provided, which has an upper surface 211, and is for example but not limited to a silicon substrate, or may be a silicon-on-insulator (SOI) substrate, or any other kind semiconductor substrate. Next, a P-type well 22 is formed beneath the upper surface 211 in the semiconductor substrate 21, and an isolation structure 23 is formed on the upper surface 211. The isolation structure 23 is for example a local oxidation of silicon (LOCOS) structure as shown in the figure, or isolation structure of another form, such as a shallow trench isolation (STI) structure. Next, as shown in FIG. 2B, a part of a gate structure 25 is formed on the upper surface 211. As shown in FIG. 2B, a dielectric layer 25a is formed on the upper surface 211, and a conductive stack layer 25b is formed on the dielectric layer 25a, as the gate electrode.

Next, as shown in FIG. 2C, two P-type lightly doped drains 24 are formed at two sides of the conductive stack layer 25b in the P-type well 22 by doping P-type impurities to regions defined by the isolation structure 23 and the conductive stack layer 25b. The process step of doping P-type impurities to the defined regions may be, for example but not limited to, an ion implantation process step which implants P-type impurities to the defined regions in the form of accelerated ions, as indicated by the dashed arrow lines 24a shown in FIG. 2C.

Next, as shown in FIG. 2D, a spacer layer 25c is formed on the sidewalls of the conductive stack layer 25b and the dielectric layer 25a, by for example but not limited to a thin film deposition process step and a self-aligned etching process step. Hence, the complete gate structure 25 is formed on the upper surface 211, wherein part of the P-type well 22 is located beneath the gate structure 25, and part of the P-type lightly doped drain 24 is located beneath the spacer layer 25c.

Next, as shown in FIG. 2E, N-type impurities are implanted to regions defined by the isolation structure 23 and the gate structure 25, or defined by a lithography process step, to form an N-type source 26 and an N-type drain 27 beneath the upper surface 211 in the P-type well 22 outside the gate structure 25. The N-type source 26 and the N-type drain 27 are located each at one side of the gate structure, and are connected to the two P-type lightly doped drains 24 respectively. The N-type source 26 and the N-type drain 27 are formed by, for example but not limited to, an ion implantation process step which implants N-type impurities to the defined regions in the form of accelerated ions as indicated by the dashed arrow lines 26a shown in FIG. 2E.

When the ESD protection device 200 and another low voltage device are concurrently manufactured on the semiconductor substrate 21, and the low voltage device has a P-type lightly doped drain, the process steps which form the P-type lightly doped drain of the low voltage device may be used to form the P-type lightly doped drain of the ESD protection device 200, so no additional process step or mask is required. As such, the ESD protection device 200 of the present invention can be manufactured by a low cost.

FIG. 2F shows an enlarged diagram of the part of FIG. 2E which is indicated by a dashed circle. In one application of this embodiment, the semiconductor substrate 21, the gate structure 25, and the source 26 are electrically connected to a ground level, and the drain 27 is electrically connected to a pad (not shown). When the drain 27 contacts a high voltage caused by static charges, the present invention is different from the prior art in that, in this embodiment, the high voltage electric field is formed between the P-type lightly doped drain 24 and the N-type drain 27. The position where the breakdown first occurs is between the P-type lightly doped drain 24 and the N-type drain 27, close to a surface 211 of the P-type substrate 21, as indicated by a star symbol shown in the figure. When an application or a circuit design requires to reduce the trigger voltage of the ESD protection device, the present invention does not require any additional manufacturing process step; instead, an implantation step which already exists in the process for forming a P-type lightly doped drain in another device in the semiconductor substrate 21 can be used to form the P-type lightly doped drain 24, such that the trigger voltage of the ESD protection device 200 can be reduced without substantially changing process steps. Furthermore, the present invention can greatly reduce the trigger voltage of the ESD protection device as compared with the prior art, because the locations where the breakdown first occurs (and then ESD is triggered) are different between the present invention and the prior art. More specifically, the location where the breakdown first occurs in the prior art is between the N-type lightly doped drain and the P-type semiconductor substrate; on the other hand, the location where the breakdown first occurs in the present invention is between the P-type lightly doped drain and the N-type drain. In the prior art, impurity concentrations nearby the location of the PN junction where the breakdown first occurs are relatively lower; on the other hand, in the present invention, impurity concentrations nearby the location of PN junction where the breakdown first occurs are relatively higher, so the breakdown voltage of the ESD protection device according to the present invention is lower than that of the prior art. In the present invention, the P-type impurity concentration of the P-type lightly doped drain 24 is higher than the P-type impurity concentration of the P-type well 22 in the ESD protection device 200, and the P-type impurity concentration of the P-type well 22 of the present invention is higher than the P-type impurity concentration of the P-type semiconductor substrate 11 in the ESD protection device 100 of the prior art; and the N-type impurity concentration of the N-type drain 27 of the present invention is higher than the N-type impurity concentration of the N-type lightly doped drain 14 in the ESD protection device 100 of the prior art.

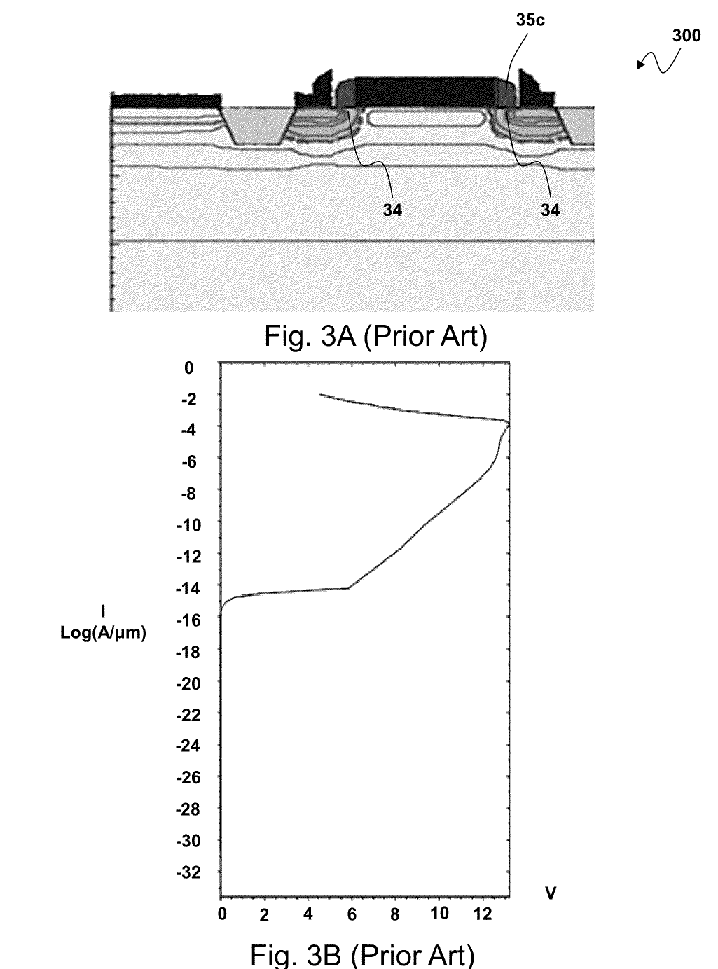

FIGS. 3A-3B show an impurity concentration profile and a voltage-current characteristic curve of the prior art ESD protection device 300 respectively. As shown in FIG. 3A, part of an N-type lightly doped drain 34 is located beneath a spacer layer 35C in the prior art ESD protection device 300. The trigger voltage according to the voltage-current characteristic curve of the ESD protection device 300 shown in FIG. 3B is about 13V.

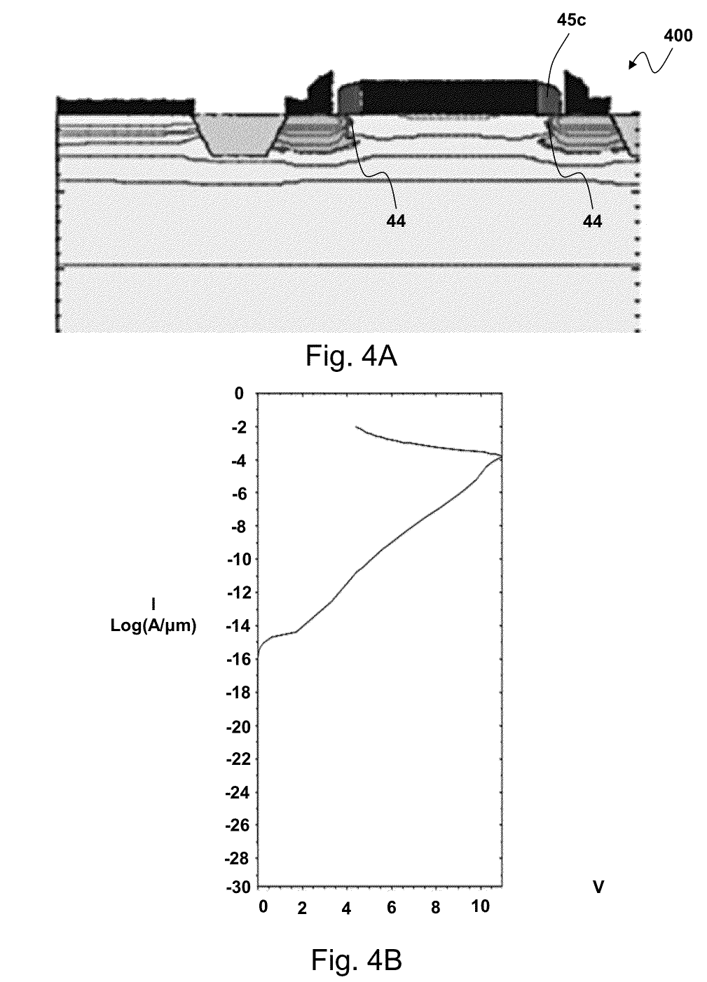

FIGS. 4A-4B show a second embodiment of the present invention. FIGS. 4A-4B show an impurity concentration profile and a voltage-current characteristic curve of an ESD protection device 400 of this embodiment respectively. As shown in FIG. 4A, part of a P-type lightly doped drain 44 is located beneath a spacer layer 45c. The P-type lightly doped drain 44 is formed by, for example but not limited to, a P-type lightly doped drain ion implantation process step and an N-type lightly doped drain ion implantation process step, wherein the P-type lightly doped drain ion implantation process step is the same process step as a process step which forms a P-type lightly doped drain in a low voltage device manufactured in the same semiconductor substrate. The N-type lightly doped drain ion implantation process step is for example but not limited to the same process step as a process step which forms an N-type lightly doped drain in another low voltage device manufactured in the same semiconductor substrate. The trigger voltage according to the voltage-current characteristic curve of the ESD protection device 400 shown in FIG. 4B is about 11V.

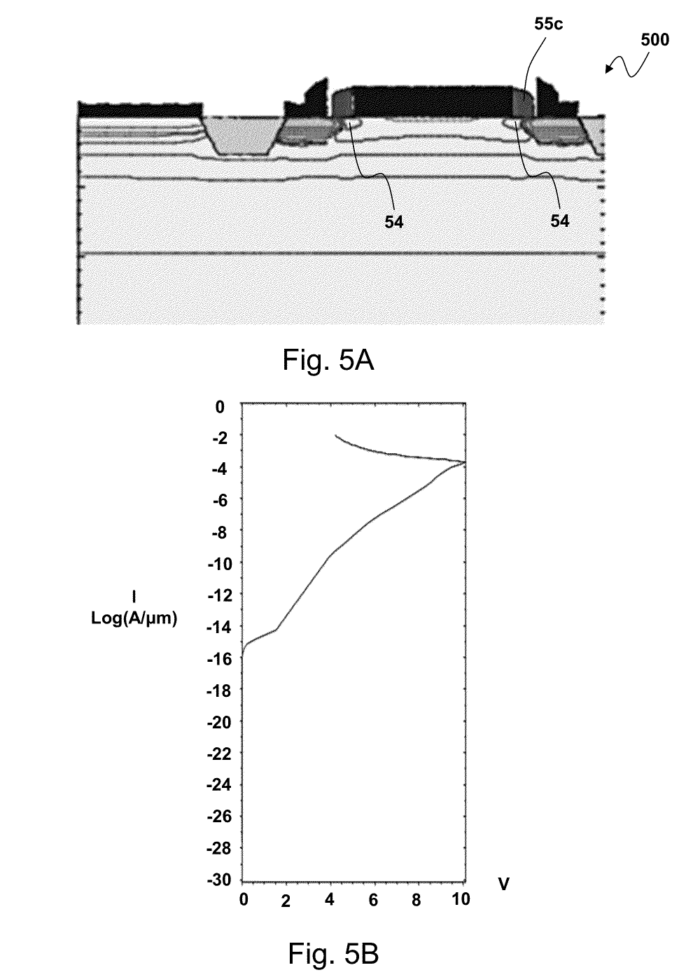

FIGS. 5A-5B show a third embodiment of the present invention. FIGS. 5A-5B show an impurity concentration profile and a voltage-current characteristic curve of an ESD protection device 500 of this embodiment respectively. As shown in FIG. 5A, part of a P-type lightly doped drain 54 is located beneath a spacer layer 55C. The P-type lightly doped drain 54 is formed by, for example but not limited to, a P-type lightly doped drain ion implantation process step, wherein the P-type lightly doped drain ion implantation process step is the same process step as a process step which forms a P-type lightly doped drain in a low voltage device manufactured in the same semiconductor substrate. The trigger voltage according to the voltage-current characteristic curve of the ESD protection device 500 shown in FIG. 5B is about 10V.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristic of the device, such as a deep well, etc., can be added; for another example, the lithography step described in the above can be replaced by electron beam lithography, X-ray lithography, etc.; for another example, in all the aforementioned embodiments, the mask and the process step of the P-type lightly doped drain are not limited to the same mask and the process of the other device in the same semiconductor substrate, but they may be changed to a specific mask and a specific process. In view of the foregoing, the spirit of the present invention should cover all such and other modifications and variations, which should be interpreted to fall within the scope of the following claims and their equivalents. An embodiment or a claim of the present invention does not need to achieve all the objectives or advantages of the present invention. The title and abstract are provided for assisting searches but not for limiting the scope of the present invention.

1. An electrostatic discharge (ESD) protection device, which is formed in a semiconductor substrate, wherein the semiconductor substrate has an upper surface, the ESD protection device comprising:
a P-type well, which is formed beneath the upper surface;
a gate structure, which is formed on the upper surface, and part of the P-type well is located beneath the gate structure;
an N-type source, which is formed in the P-type well beneath the upper surface, and the N-type source is located at one side of the gate structure;
an N-type drain, which is formed in the P-type well beneath the upper surface, and the N-type drain is located at another side of the gate structure;
wherein the gate structure separates the N-type source and the N-type drain, and the gate structure includes:
a dielectric layer, which is formed on the upper surface;
a conductive stack layer, which is formed on the dielectric layer, as a gate electrode; and
a spacer layer, which is formed on sidewalls of the conductive stack layer; and
a first P-type lightly doped drain, which is formed in the P-type well beneath the upper surface and directly contacts the P-type well, and at least part of the first P-type lightly doped drain is located beneath the spacer layer;
wherein the first P-type lightly doped drain and the N-type drain form a PN junction, which is the first location to break down when the N-type drain receives a voltage caused by static charges, to trigger an ESD protection.

2. The ESD protection device of claim 1, wherein the first P-type lightly doped drain and a second P-type lightly doped drain of a low voltage device in the semiconductor substrate are formed by a same process step.

3. The ESD protection device of claim 1, wherein the gate structure is electrically connected to a ground level in a normal operation.

4. The ESD protection device of claim 1, wherein the first P-type lightly doped drain is formed by a P-type lightly doped drain ion implantation process step and an N-type lightly doped drain ion implantation process step, wherein the P-type lightly doped drain ion implantation process step is a same process step as a process step which forms a second P-type lightly doped drain in a low voltage device in the semiconductor substrate.

5. The ESD protection device of claim 1, wherein a P-type impurity concentration of the first P-type lightly doped drain is higher than a P-type impurity concentration of the P-type well.

6. A manufacturing method of an electrostatic discharge (ESD) protection device comprising:
providing a semiconductor substrate with an upper surface;
forming a P-type well beneath the upper surface;
forming a gate structure on the upper surface, and part of the P-type well is located beneath the gate structure;
forming an N-type source in the P-type well beneath the upper surface, and the N-type source is located at one side of the gate structure;
forming an N-type drain in the P-type well beneath the upper surface, and the N-type drain is located at another side of the gate structure;
wherein the gate structure separates the N-type source and the N-type drain, and the gate structure includes:
a dielectric layer, which is formed on the upper surface;
a conductive stack layer, which is formed on the dielectric layer, as a gate electrode; and
a spacer layer, which is formed on sidewalls of the conductive stack layer; and
forming a first P-type lightly doped drain in the P-type well beneath the upper surface, wherein the first P-type lightly doped drain directly contacts the P-type well, and at least part of the first P-type lightly doped drain is located beneath the spacer layer;
wherein the first P-type lightly doped drain and the N-type drain form a PN junction, which is the first location to break down when the N-t drain receives a voltage caused by static charges, to trigger an ESD protection.

7. The manufacturing method of claim 6, wherein the first P-type lightly doped drain and a second P-type lightly doped drain of a low voltage device are formed by a same process step in the semiconductor substrate.

8. The manufacturing method of claim 6, wherein the gate structure is electrically connected to a ground level in a normal operation.

9. The manufacturing method of claim 6, wherein the first P-type lightly doped drain is formed by a P-type lightly doped drain ion implantation process step and an N-type lightly doped drain ion implantation process step, wherein the P-type lightly doped drain ion implantation process step is a same process step as a process step which forms a second P-type lightly doped drain in a low voltage device in the semiconductor substrate.

10. The manufacturing method of claim 6, wherein a P-type impurity concentration of the first P-type lightly doped drain is higher than a P-type impurity concentration of the F-type well.
